(19) United States
(12) Patent Application Publication
(10) Pub. No.: US 2005/0012516 A1
(43) Pub. Date: Jan. 20, 2005

(54) Burn-in socket adapt to assembly sensor thereon

(76) Inventor: Sung-Pei Hou, Tu-chen (TW)

Correspondence Address: WEI TE CHUNG;FOXCONN INTERNATIONAL, INC., 1650 MEMOREX DRIVE, SANTA CLARA, CA, 95050, US

(21) Appl. No.: 10/894,598

(22) Filed: Jul. 19, 2004

(30) Foreign Application Priority Data
Jul. 18, 2003 (TW) 92213183

(51) Int. Cl. G01R 31/26

(52) U.S. Cl. 324/765

(57) ABSTRACT

A burn-in socket (1) includes a base (10) receiving an IC and a number of contacts (12) received in the base, and a pressing member (14). The base defines a slot (1024) in a wall thereof and having a step (1029) under the slot. A bore (1026) is defined in and through the wall in a lateral direction. The pressing member included an elongated lever (144) and a pair of screws (140) for securing the lever on the wall. A sensor is received in the bore and sandwiched by the lever and the step to provide signals to a controller during being operated at a high temperature. The controller can reliably control the temperature of the whole assembly in light of the signals from the sensor, thereby avoiding damage of the IC by exorbitant temperature.

### BACKGROUND OF THE INVENTION

1. Field of the Invention

The present invention relates to a burn-in socket for electrically connecting an electronic package such as an integrated circuit (IC) with a circuit substrate such as a burn-in board.

2. Description of the Prior Art

Electronic packages, such as integrated circuits (ICs), are miniaturized electronic devices in which a number of active and passive circuit elements are located on or within a continuous body of material to perform certain function of a complete circuit. To ensure reliability in use, the ICs require prior burning in to test their durability. The ICs are operated at a high temperature for an extended period of time to accelerate potential failure points. This helps eliminate early product failures once the ICs are sold and/or assembled onto electronic end products. A burn-in socket is used to receive an IC therein, and electrically connects the IC with a burn-in board for operation of the IC at high temperature. Normally, a temperature sensor with a digital output is mounted near the IC to measure the temperature of the assembly. The digital output is connected with a controller. The sensor provides signals to the controller through the digital output. The controller can control the temperature of the assembly in light of the signals from the sensor, thereby avoiding damage of the IC by exorbitant temperature. Pertinent example of the burn-in socket is disclosed in U.S. Pat. No. 5,172,049.

Generally, a burn-in socket comprises a socket, an IC mounted onto the socket and electrically connected with a number of electrical terminals of the socket, a cap mounted on a top side of the socket and having a generally rectangular first window in a middle portion thereof, and a heat sink mounted on a top surface of the IC and in the first window of the cap. A heater is mounted in the cap to heat the assembly. A temperature sensor is mounted in the cap over the heater to measure the temperature of the assembly. The sensor has a wire connected with and providing signals to a controller. During burn-in, the controller can control the temperature of the assembly in light of the signals from the sensor, thereby avoiding damage of the IC by exorbitant temperature.

However, in the above-mentioned burn-in socket, the sensor is mounted on the cap away from the IC. The temperature measured by the sensor is liable to be higher than the actual temperature of the IC. The IC is operated under a temperature which is lower than a desired temperature. Therefore, all early product failures are unlikely to be eliminated before sale and/or being assembled onto electronics end products.

In the view of the above, a new burn-in socket that overcomes the above-mentioned disadvantages is desired.

### SUMMARY OF THE INVENTION

An object of the invention is to provide a burn-in socket for electrically connecting an electronic package such as an integrated circuit (IC) with a circuit substrate such as a burn-in board, wherein the burn-in socket is configured so as to hold a sensor adjacent the IC thereby reliably controlling the IC in a desired temperature during burn-in.

To achieve the above-mentioned object, a burn-in socket in accordance with a preferred embodiment is provided. The burn-in socket comprises an insulative base, a multiplicity of electrical contacts received in the base, and a pressing member. The base defines an elongated slot in a front wall thereof extending in a lengthwise direction. A bore is defined in and through the front wall in a lateral direction. The pressing member comprises an elongated lever and a pair of screws for securing the lever on the front wall. A sensor is received in the bore and securely sandwiched by the lever and the step of the base to provide signals to a controller during being operated at high temperature. The controller can reliably control the temperature of the whole assembly in light of the signals from the sensor, thereby avoiding damage of the IC by exorbitant temperature.

Other objects, advantages or novel features of the invention will become more apparent from the following detailed description when taken in adjunction with the accompanying drawings, in which:

### BRIEF DESCRIPTION OF THE DRAWINGS

FIG. 1 is an exploded, isometric view of a burn-in socket with a temperature sensor in accordance with the preferred embodiment of the present invention;

FIG. 2 is an assembled, isometric of the burn-in socket and the sensor of FIG. 1;

FIG. 3 is an assembled, isometric view of the burn-in socket and the sensor of FIG. 1 with the part thereof cut, showing the burn-in socket and the sensor in an uncompleted assembly state; and

FIG. 4 is similar to FIG. 3, but showing the burn-in socket and the sensor in a complete assembly state.

### DETAILED DESCRIPTION OF THE PREFERRED EMBODIMENT OF THE INVNETION

Reference will now be made to the drawings to describe the present invention in detail.

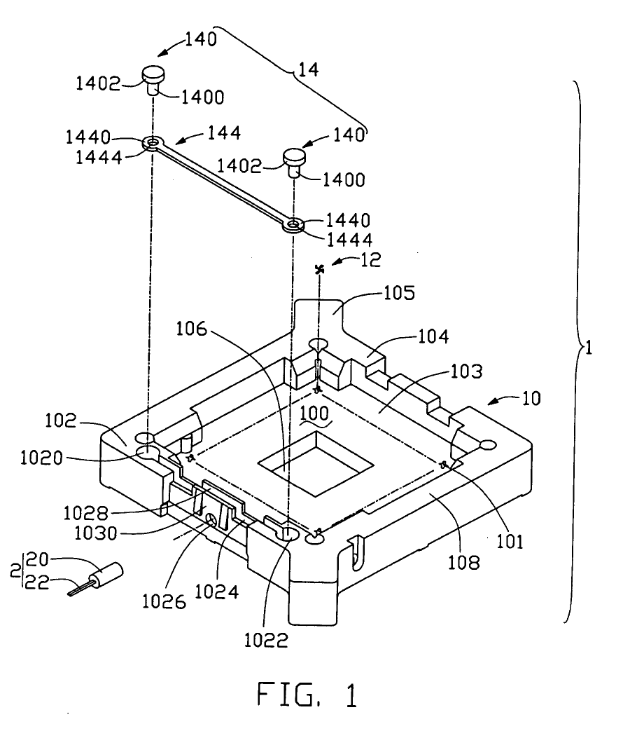

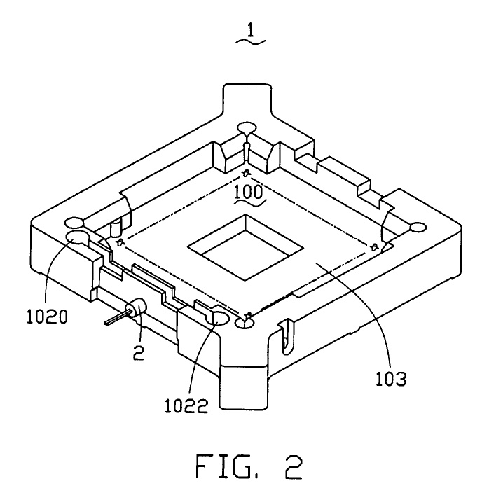

Referring to FIGS. 1 and 2, there is shown an isometric, exploded view of a burn-in socket 1 with a temperature sensor 2 of the invention. The burn-in socket 1 is used for electrically connecting an integrated circuit (IC) (not shown) with a burn-in board (not shown). The sensor 2 comprises a generally cylindrical body 20 and wires 22 for being connected with a controller (not shown).

The burn-in socket 1 comprises an insulative base 10, a multiplicity of electrical contacts 12 received in the base 10, and a pressing member 14 for securely holding the sensor 2 on the burn-in socket 1.

The base 10 comprises a body portion 100, a pair of front and end walls 102, 104 extending upwardly from front and end sides of the body portion 100, and a pair of sidewalls 108 extending upwardly from two opposite lateral sides of the body portion 100 respectively. The front and end walls 102, 104 and sidewalls 108 form a generally rectangular cavity 103 therebetween for receiving the IC therein. A pair of projections 105 is formed at two ends of a diagonal of the base 10. A recess 106 is defined in a middle portion of the body portion 100. A multiplicity of passageways 101 is defined in the body portion 100 therethrough and arranged around the recess 106.

The contact 12 are accommodated in the passageways 101 respectively. Each contact 12 comprises a first contact portion (not labeled) for electrically contacting the IC and a second contact portion (not labeled) for electrically contacting the burn-in board. Thus, the burn-in socket 1 can connect the IC with the burn-in board.

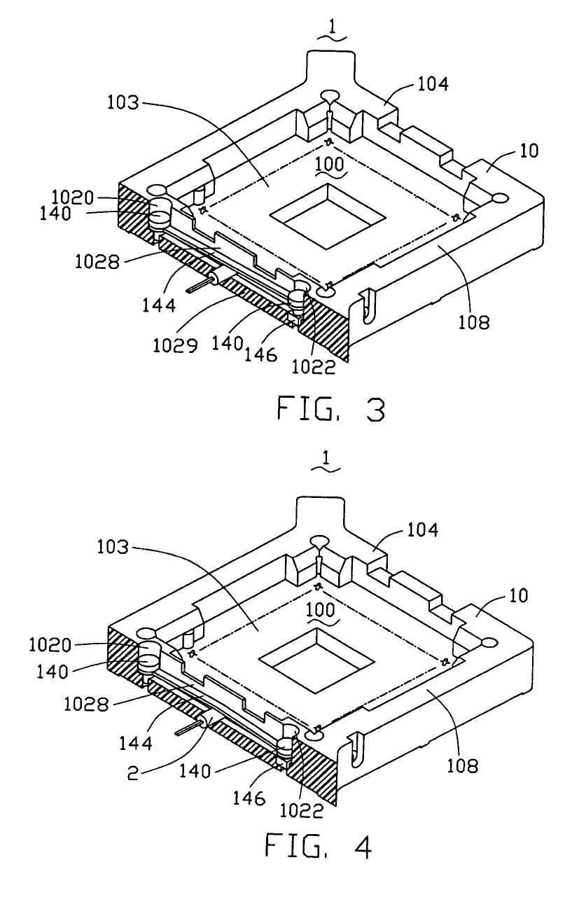

Referring to FIGS. 1 and 3, an elongated slot 1024 is defined in the front wall 102 of the base 10, the slot 1024 extending in a lengthwise direction of the front wall 102. The base 10 forms first and second tabs 1028, 1030, and a step 1029 under the slot 1024. A bore 1026 is defined in and through a middle portion of the tabs 1028, 1030 of the front wall 102 in a lateral direction, a diameter of the bore 1026 generally equal to a diameter of the body 20 of the sensor 2. A pair of first and second step holes 1020, 1022 is defined in two opposite sides of the front wall 102 respectively, the first and second step holes 1020, 1022 communicated with the slot 1024 and extending through the front wall 102. Each of the first and second step holes 1020, 1022 comprises an upper hole and a lower hole. The lower hole defines an internal thread, and a diameter of the lower hole is smaller than a diameter of the upper hole. A reinforcing member 146 is embedded in the front wall 102 at an end of the step 1029. The reinforcing member 146 defines an aperture (not shown) in a middle portion thereof for receiving the sensor 2, the aperture communicated with the second step holes 1022.

Referring to FIG. 1, the pressing member 14 comprises an elongated lever 144 and a pair of screws 140. The lever 144 forms a pair of circular portions 1440 at two opposite ends thereof, each circular portion 1440 defining a hollow 1444 in a middle thereof. A diameter of each circular portion 1440 is smaller than a diameter of the upper hole of each of the first and second step holes 1020, 1022. A diameter of the hollow 1444 is equal to the diameter of the lower hole of each of the first and second step holes 1020, 1022. Each of the screws 140 comprises a cap 1402 and a screw pin 1400.

Referring to FIGS. 3 and 4, during assembly of the sensor and the burn-in socket, the lever 144 is assembled into the slot 1024 of the front wall 102 with the circular portions 1440 thereof accommodated in the upper holes of the first and second holes 1020, 1022 respectively. One screw 140 is inserted in the first step hole 1020 and engages in the lower hole of the first step hole 1020. In this uncompleted state, the body 20 of the sensor 2 can be inserted into or withdrawn from the bores 1026 freely. The other screw 140 is inserted in the second step hole 1022 through the aperture of the reinforcing member 146 and engages in the lower hole of the second step hole 1022. In this complete state, the sensor 2 is securely sandwiched between a middle portion of the lever 144 and the step of the front wall 102.

In used, the burn-in socket is mounted onto and electrically connected with the burn-in board. The IC is received in the cavity 103 and electrically connected with the contacts 12 of the burn-in socket 1. In this position, the burn-in socket 1 and the IC can be operated at high temperature for an extended period of time to accelerate potential failure points. During operation, the sensor 2 provides signals to a controller (not shown) via the wires 22 thereof. The controller can reliably control the temperature of the whole assembly in light of the signals from the sensor 2, thereby avoiding damage of the IC by exorbitant temperature. After burn-in, the above-mentioned actions are repeated, and a new IC (not shown) can be assembled in the burn-in socket 1 to be operated.

From the foregoing it will be recognized that the principles of the invention may be employed in various arrangements to obtain the features, advantages and benefits described above. It is to be understood, therefore, that even though numerous characteristics and advantages of the invention have been set forth together with details of the structure and function of the invention, this disclosure is to be considered illustrative only. Various changes and modifications may be made in detail, especially in matters of size, shape and arrangements of parts, without departing from the spirit and scope of the invention as defined by the appended claims.

1. A burn-in socket comprising:
an insulative base defining a generally rectangular cavity in a middle portion thereof and having a raised wall, a plurality of passageways defined in the base under the cavity, the raised wall defining an elongated slot extending in a lengthwise direction thereof and a bore extending in a lateral direction thereof;
a plurality of electrical contacts received in the passageways of the base respectively; and
a pressing member received in the slot of the base and a sensor securely secured in the bore.

2. The burn-in socket as claimed in claim 1, wherein a pair of step holes is defined in two opposite sides of the raised wall respectively, each of the step holes forming an upper hole and a lower hole with an internal thread thereat.

3. The burn-in socket as claimed in claim 2, wherein a reinforcing member is embedded in the raised wall, the reinforcing member defining an aperture communicating with the step hole.

4. The burn-in socket as claimed in claim 3, wherein the pressing member comprises an elongated lever forming a pair of circular portions with hollows and a pair of screws.

5. The burn-in socket as claimed in claim 4, wherein the lever is received in the slot with the circular portions received in the upper holes of the step holes respectively and the screws engaging in the lower holes of the step holes respectively, thereby securing the sensor.

6. A burn-in socket assembly, adapted to receive an integrated circuit (IC) therein and be operated at a high temperature for an extended period of time to accelerate potential failure points, the burn-in socket assembly comprising an insulative base accommodating the IC therein, a plurality of electrical contacts received in the base to electrically contact the IC, a sensor received in the base, and a pressing member assembled on the base to securely hold the sensor, the sensor being capable of providing signals during operation.
